(19) United States
(12) Patent Application Publication
(10) Pub. No.: US 2015/0149517 A1
(43) Pub. Date: May 28, 2015

(54) LOGIC DEVICE AND METHOD OF PERFORMING A LOGICAL OPERATION

(71) Applicant: University of the West of England, Bristol (GB)

(72) Inventor: Ella Matthews, Bristol (GB)

(21) Appl. No.: 14/089,191

(22) Filed: Nov. 25, 2013

(51) Int. Cl. H03K 19/20; H03K 19/08

(52) U.S. Cl. CPC H03K 19/20; H03K 19/08
USPC 708/190

(57) ABSTRACT

The invention provides a logic device, e.g. a Boolean logic gate, comprising: a memristor having: an input for receiving a sequence of voltage states which represent a sequence of logical inputs for a logical operation, and an output for an output current response triggered by the sequence of voltage states; and a determining unit arranged to determine an output of the logical operation from the output current response.

### FIELD OF THE INVENTION

The present invention relates to a logic device.

The present invention also relates to a method of performing a logical operation.

### BACKGROUND OF THE INVENTION

A logic gate is a physical device that implements a Boolean function, i.e. it performs a logical operation on one or more logical inputs having values of logical “1” or logical “0” and produces a single logical output having a value of logical “1” or logical “0”. Examples of logic gates include the AND logic gate, the OR logic gate, the NOT logic gate, the NAND logic gate, the NOR logic gate, the XOR logic gate and the XNOR logic gate.

Logic gates are fundamental components of many, if not all, electronic devices. Logic gates can be combined to make Arithmetic Logic Units (ALUs), such as the Adder and the Half-Adder. The Adder and the Half-Adder perform arithmetic addition, which is the basis of essentially every computational operation. As such, logic gates are fundamental components of the Central Processing Units (CPUs) of computers and other electronic devices. These logic and addition operations are usually performed with voltage and current changes.

It is important for the operation of an electronic device (such as a CPU of a computer) that the device has enough different types of logic gate to perform all possible Boolean logical operations. When this constraint is satisfied, the device is said to be “Turing complete”.

Where the output of a logic device depends only on the condition (i.e. logical value(s)) of the latest input(s) to the logic device, the logic device is known as a “combinational” logic device. If instead the output of the logic device depends not only on the condition of the latest input(s) but also on the condition of earlier input(s), the logic device is known as a “sequential” logic device. Sequential logic devices contain a memory element that stores information about the condition of the earlier input(s) (as a particular state of the memory element).

Logic devices are primarily implemented in electronic logic circuits using diodes or transistors acting as electronic switches. A main driving force in computation for the past 50 years has been the further miniaturisation of computer components such as logic gates or ALUs, so that more of these components can be fitted on a processor. This should enable the processor to carry out more complex operations and to perform operations more quickly. However, further decreases in the size of such components is hampered by the difficulty of making increasingly small transistors out of silicon and dealing with the increased heat generated by packing the components on the processor in ever increasing densities.

Therefore, there exists a problem of decreasing the size of a logic device such as a logic gate relative to a conventional logic device comprising silicon transistors.

Memristors are electronic components, often on the nanoscale, that essentially act as resistors with a memory. This combination of functionality and scalability has led to the suggestion that memristors are a potential route to increasing computation complexity in terms of Moore's Law (see Kumar, Memristor—Why Do We Have to Know About It?, IETE Tech. Rev., 26, 3-6, (2009)). Memristor theory has been successfully applied to describe the operation of synapses and the processes of learning in snails and amoeba. Therefore, memristors have the potential to become vital components in attempts to create brain-like (neuromorphic) computers that are capable of learning and possibly higher level functions, such as intelligence.

Four circuit properties are of interest when describing circuits: the current, I, voltage, V, charge, q, and magnetic flux, φ. Circuits can be viewed as combinations of fundamental circuit elements, each of which relates two of these circuit properties. The three well-known fundamental circuit elements are the resistor, which relates V to I, the inductor (V to φ) and the capacitor (V to q). A fourth fundamental circuit element was added in 1971, when Chua predicted the existence of a device that would relate q to φ, the memristor (see Chua, Memristor—The Missing Circuit Element, IEEE Trans. Circuit Theory, 18, 507-510, (1971)). Because I and V are time differentials of q and φ, memristors produce distinctive non-linear I-V curves that have three important features: (1) hysteresis (memory); (2) zero current at zero voltage; and (3) A.C. frequency dependence (the size of the hysteresis is related to frequency and it shrinks to nothing above a critical frequency).

Prior to 2008, many memristors had been reported in the literature, but Strukov et al were the first to relate a manufactured device to Chua's theoretical predictions (see Strukov et al, The Missing Memristor Found, Nature, 453, 80-83 (2008)). However, both Strukov et al's device and their model lack a measurable magnetic flux related to the memristance. This lack has led to scientific debate, as some have asserted that a Chua memristor had not been created, while others have taken the view that the magnetic flux may be only a theoretical construct and/or that it is the non-linear I-V relationship that defines the memristor.

Memristors have been credited with the possibility of revolutionising many areas of computational science such as memory and neuromorphic computation. Since the announcement of the first documented two-terminal memristor (the first three-terminal memristor having been made contemporary with Chua's theoretical prediction) researchers have been eager to experiment with memristors, but they are difficult to synthesize and not yet commercially available. An important break-through in this area was the announcement of a solution processed memristor (see Gergel-Hackett et al, A flexible solution-processed memristor, IEEE electron Device Letters, 30:706-708, 2009). Although this memristor used the same ‘memristive’ material as HP's nanoscale memristor, TiO₂, the electrode material was aluminium rather than platinum. The authors stated that the aluminium did not have an effect on the mechanism because switching was also seen with gold electrodes. However, another recently announced memristor device with aluminium electrodes (with a graphene oxide substrate rather than TiO₂) has been shown to have different I-V characteristics if gold is used as an electrode (see Jeong et al, Graphene oxide thin films for flexible non-volatile memory applications, Nanoletters, 10:4381-4386, 2010). Similarly, including Al₂O₃ in gold electrode and TiO₂ junctions was found to promote hysteresis. Finally, it has been stated and widely accepted that memristors should be nanoscale devices due to reasoning based on the device thickness term in the equations presented in Kumar, Memristor—Why Do We Have to Know About It?, IETE Tech. Rev., 26, 3-6, (2009).

ReRAM is a field closely associated with memristors. Its actual relation is somewhat controversial as it has been claimed that all resistive switching memories are memristors. This definition would implicitly include ReRAM devices. In this application it is considered that the term “memristor” includes resistive switching memories such as ReRAM devices, i.e. that switching memories such as ReRAM devices are examples of memristors, and the term “memristor” is used accordingly.

In the field of ReRAM there are two types of switching: Unipolar switching (UPS) and Bipolar Switching (BPS). BPS closely resembles Chua's memristor plots, whereas UPS involves a much more definite jump in resistance values, usually an order of magnitude at least, although it still fits the definition for memristance. Both BPS and UPS have been reported in Pt/TiO₂/Pt electrodes and resistive switching has been recorded in TiO₂ thin films grown by atomic layer deposition. Magnéli phases, a reduced-oxygen-content type of TiO₂, have been recorded in conduction filaments (widely believed to be the cause of switching in ReRAM) in ReRAM devices and is implicated in memristor operation.

Specific examples of memristors that have been reported in the literature include:
1. Widrow's Adaline memistors circa 1960 (see Widrow, An adaptive ‘adaline’ neuron using chemical ‘memristors’, Technical Report, 1960).
2. HP's TiO₂/TiO₂₋ₓ memristor (see Troitsky et al, Synth. Met., 129:39, 2002).
3. Erokhin & Fontana's PEO-PANI memristor (see Erokhin et al, Electrochemically controlled polymeric device: a memristor (and more) found two years ago, arXiv:0807:0333v1, [cond-mat.soft], 2008 or Erokhin et al, Organic memristor and bio-inspired information processing, International journal of Unconventional Computing, 6:15-32, 2009).
4. Flexible TiO₂ and plastic memristor (see Gergel-Hackett et al, A flexible solution-processed memristor, IEEE Electron Device Letters, 30:706-708, 2009)
5. Conducting polymer with Au nanoparticles (see Erokhin et al, Conducting polymer-solid electrolyte fibrillar composite material for adaptive networks, Soft Matter, 2:870-874, 2006).
6. Au/Ag memristor.

Both memristors and ReRAM have been suggested as possible low-power next-generation computer memory technology. However, the field of ReRAM has been around for 20 years and has not yet produced a commercial product. For example, Hewlett-Packard (the company that discovered the Strukov memristor) has not yet released a computer memory offering based on their memristor.

It is known to make logic gates using memristors. Strukov et al (see Borghetti et al, ‘Memristive’ switches enable ‘stateful’ logic operations via material implication, Nature, 464, 878-876 (2010)) resorted to using implication logic to design logic gates which required two memrsitors (IMP-FALSE logic is Turing complete). The most notable Boolean logic gates were simulated by Pershin and di Ventra (see Pershin et al, Neuromorphic, Digital and Quantum Computation with Memory Circuit Elements, Proc. IEEE, 100, 2071-2080, 2012) and required a memcapacitor, three or four memristive systems and a resistor. Before the gate was sent the two bits of data, a set of initialization pulses were required to be sent to put the gate into the correct state to give the correct answer. This system, however, is not true Boolean logic because these initialization pulses were different dependent on what the logic to follow would be. Thus the gate, cannot be considered to be operating only on the two bits of input data and is not a simple Boolean logic gate (it is a Turing machine doing a computation on several bits of data (Boolean input pulses and initialization pulses) which is capable of modelling a Boolean logic gate). It is also important to note that this scheme was tested with memristor emulators, not real devices. There have been other more complex designs for memristor based Boolean logic gates, the simplest of which requires 11 circuit elements (see U.S. Pat. No. 8,274,312B).

Therefore, there exists a problem of producing a memristor-based logic device that is less complex than the existing devices discussed above, and/or that is capable of carrying out a Boolean logical operation.

### SUMMARY OF THE INVENTION

As previously reported by the present inventor in Gale 2012 (Gale et al, Observation and Characterisation of Memristor Current Spikes and their Application to Neuromorphic Computation, In: 2012 International Conference on Numerical Analysis and Applied Mathematics (ICNAAM 2012), AIP Conference Proceedings 1479, pp 1898-1901, 2012), a feature of memristors is that they display a spike in their current output in response to a voltage change across the memristor. The current spike is highly reproducible and its characteristics are related to the size and to the sign of the voltage change. After the current spike, the memristor current relaxes over a period of time to a stable long-term equilibrium value (which is a predictable and reproducible value). The time taken for the memristor current to return to the equilibrium value may be referred to as an equilibration time, or a relaxation time, of the memristor. The contents of Gale 2012 are incorporated herein by reference.

Such current spikes have been observed by other researchers in their memristors. However, they are usually overlooked, or attributed to artifacts arising from the experimental setup, or not reported at all (many researchers only report the I-V curves to demonstrate that they have a memristor). Regardless of how the current spikes arise, they are impossible (as far as the present inventor knows and the literature states) to remove.

The present inventor has realised that a single memristor can be used as a logic device, for example as a Boolean logic gate, by making use of the physical properties of these current spikes. In particular, the present inventor has realised that if the memristor is caused to generate two current spikes in quick succession, i.e. by changing the voltage across the memristor twice in quick succession (i.e. separated by a time period less than the equilibration time of the memristor) the two current spikes will interact. If the two current spikes interact, the memristor current at, or after, the time that the second current spike is generated will be different to the current that would be expected if the second current spike were generated in isolation (i.e. at a time when the memristor current is equal to an equilibrium current). Instead, the memristor current will depend on the non-equilibrium state of the memristor at the time of generating the second current spike in addition to the direction and the magnitude of the second voltage change.

The non-equilibrium state of the memristor at the time of generating the second current spike depends on the first voltage change (the memristor is in a non-equilibrium state because it has not had sufficient time to equilibrate to the first voltage change). Therefore, the output current of the memristor measured at or after the time that the second current spike is generated will depend on both the first and second voltage changes (and therefore also on the first and second voltages, which determine the sizes of the first and second voltage changes). The memristor may be considered as performing an operation, the inputs of which are the voltage changes (or the voltages) and the output of which is (some property of) the output current at, or after, the time that the second current spike is generated.

Essentially, the memristor may be considered as having a short term memory, so that the memristor remembers information about the first voltage change (i.e. it is in a non-equilibrium state that depends on the first voltage change) at the time of the second voltage change, provided that the two voltage changes are separated in time by less than the equilibration time of the memristor. The memristor may therefore be considered to be performing sequential logic.

The present inventor has realised that by supplying appropriate voltages to the memristor as the first and second voltages (i.e. so that they can be said to represent, or to be associated with, input logical values to a logical operation) the memristor can be used to determine the output of a logical operation by assigning a suitable output logical value based on (one or more properties of) the output current of the memristor.

Therefore, at its most general the present invention relates to supplying a sequence of voltages representing a sequence of logical inputs of a logical operation to a memristor and determining a logical output of the logical operation based on a property of an output current response of the memristor.

According to a first aspect of the present invention there is provided a logic device comprising:

a memristor having:
an input for receiving a sequence of voltage states which represent a sequence of logical inputs for a logical operation, and
an output for an output current response triggered by the sequence of voltage states; and

a determining unit arranged to determine an output of the logical operation from the output current response.

The logic device according to the first aspect of the present invention is usable to determine an output of a logical operation performed on a sequence of logical inputs represented by a sequence of voltage states input into the memristor. Where the voltage states are separated in time by less than an equilibration time of the memristor, the output current response of the memristor will depend on the specific sequence of voltage states (rather than depending only on the most recent voltage state). Therefore, the output current response of the memristor may be indicative of the specific sequence of voltage states input into the memristor, and therefore also indicative of the specific sequence of logical inputs represented by the sequence of voltage states. The determining unit may therefore use the output current response of the memristor to determine an output of a logical operation performed on the sequence of logical inputs.

In the logic device according to the first aspect of the present invention a single memristor may be used, rather than the approximately 2 to 6 transistors that are used in conventional logic gates. In addition, a memristor is significantly smaller than a transistor, meaning that the total size reduction of the logic device according to the first aspect of the invention relative to a conventional transistor based logic device may be approximately 50 fold. A memristor is also more energy efficient than a transistor, because a memristor may be operated with very small power-draw and/or currents, e.g. only requiring current when in use. Therefore, a memristor based logic device may run cooler (and therefore be cheaper and more environmentally friendly) than transistor based logic devices.

Therefore, by making a logic device using a memristor rather than a plurality of transistors it may be possible to fit many more logic devices on e.g. a CPU, and/or to make the CPU more energy efficient. This should enable the CPU to carry out more complex operations and to perform operations faster and more efficiently. Relative to a logic device comprising a plurality of memristors, as discussed above, the logic device according to the first aspect of the present invention will be significantly smaller and less complicated to operate.

The logic device according to the first aspect of the present invention may have any one, or, to the extent that they are compatible, any combination of the following optional features.

The term “memristor” may include resistive switching memories such as ReRAM devices, i.e. resistive switching devices such as ReRAM devices may be examples of memristors.

The term “memristor” may mean a device having a non-linear I-V relationship.

The logic device may comprise a current detector arranged to detect a property of the output current response of the memristor.

The determining unit may be configured to determine the output of the logical operation based on the detected property of the output current response of the memristor.

The logic device may include a current detector configured to detect a sign of an output current of the memristor, and the determining unit may be configured to determine the output of the logical operation based on the detected sign of the output current. The sign of the output current may change depending on the properties (i.e. magnitude and/or sign) of the voltage states and/or their order. Therefore, the sign of the output current may be indicative of the output of a logical operation performed on the sequence of voltage states. The determining unit may therefore be able to use the sign of the output current to determine the output of a logical operation performed on the sequence of voltage states.

The logic device may include a current detector configured to detect a magnitude of an output current of the memristor, and the determining unit may be configured to determine the output of the logical operation based on the detected magnitude of the output current. The magnitude of the output current may change depending on the properties (i.e. magnitude and/or sign) of the voltage states and/or their order. Therefore, the magnitude of the output current may be indicative of the output of a logical operation performed on the sequence of voltage states. The determining unit may therefore be able to use the magnitude of the output current to determine the output of a logical operation performed on the sequence of voltage states.

The logic device may comprise a Boolean logic gate. In other words, the logic device may be a logic gate that carries out Boolean logic.

The logic device may comprise one or more of: an OR logic gate, an XOR logic gate, a NOR logic gate, a NOT logic gate, an AND logic gate, a NAND logic gate, an XNOR logic gate, an adder or a half-adder.

The logic device may be a sequential logic device. In other words, the output of the logic device may depend on both a current (present) logical input to or existing at the logic device and an earlier logical input to the logic device. Essentially, the logic device may be considered as having a memory that stores the state of the earlier logical input for a period of time, so that this data (i.e. bit of information) is available at the time of inputting the later logical input (i.e. a further bit of information).

The memristor may be a two terminal memristor. In other words, the memristor may have a single input and a single output. A memristor having one input and one output may be referred to as a one-port memristor. However, the present invention may also be applicable to memristors having a different number of terminals, for example the present invention may also be applicable to a three-terminal memristor.

The determining unit may be arranged to determine the sum of the sequence of logical inputs from the output current response. In other words, the logic device may function as an adder, in that it performs addition of the logical inputs. For example, where the logical inputs are [1,1,0], the sum of the logical inputs is 2 (1+1+0).

The determining unit may be arranged to determine the sum of a sequence of three logical inputs from the output current triggered by a sequence of three voltage states representing the three logical inputs.

The determining unit may be arranged to determine the sum of a sequence of logical inputs based on a magnitude of a maximum positive current of the current response, e.g. the maximum positive current of the current response in a predetermined time period or time range, for example a predetermined time range that starts at the time of inputting the first logical input. For example, in some embodiments, where the maximum positive current is within a first voltage range (e.g. I₁ to I₂ where I₂>I₁) the sum may be determined as 0, where it is in a second voltage range (e.g. I₂ to I₃ where I₃>I₂) the sum may be determined as 1, where it is in a third voltage range (e.g. I₃ to I₄ where I₄>I₃) the sum may be determined as 2 and where it is in a fourth voltage range (e.g. >I₄) the sum may be determined as 3. Therefore, it may be possible to directly determine the result of the summation operation from the output current response. The memristor can therefore be considered to be performing physical summation (without a summation bit).

The determining unit may be arranged to determine a first logical output Cₒᵤₜ and a second logical output S from the current response, wherein the sum of the sequence of logical inputs is given by:

sum=(2×Cₒᵤₜ)+S

In other words, the output of the logic device may be the same as the output of a conventional adder. Each of the logical outputs Cₒᵤₜ and S may take the values of logical 1 or logical 0.

The determining unit may also be arranged to determine other information from the output current response, for example whether the input includes a 1, and/or whether the input includes a 0, and/or (from the precise value of the output current at time t2 and a precise thresholding of the current output) where the 0 input is positioned in the input sequences [011], [101] and [110] and where the 1 input is positioned in the input sequences [001], [010], and [100]. This information may be determined by considering the magnitude of the negative response current, e.g. within a predetermined time period/time range.

According to a second aspect of the present invention there is provided a logic device comprising:

a memristor having an input and an output;

a current detector arranged to detect a property of an output current spike from the memristor; and

a logical operation determining unit arranged to determine an output of a logical operation based on the detected property of the output current spike that is output in response to a sequence of voltage changes applied at the input of the memristor;

wherein the sequence of voltage changes represent a sequence of logical inputs for the logical operation.

The logic device according to the second aspect of the present invention may have one or more of the optional features of the first aspect of the present invention discussed above, where compatible.

According to a third aspect of the present invention there is provided a method of performing a logical operation, comprising: inputting a sequence of voltage states into a memristor to trigger an output current response; and using a property of the output current response of the memristor to determine an output of a logical operation performed on the sequence of voltage states.

The output current of the memristor may depend on the specific sequence of the voltage states (e.g. if the voltage states are separated by less than an equilibration time of the memristor), i.e. the size and/or magnitude and/or order of the voltage states. Therefore, the property of the output current of the memristor may depend on, and be indicative of, the specific sequence of voltage states input into the memristor. As such, the property of the output current response of the memristor may be used to determine an output of a logical operation performed on the sequence of voltage states.

In the method according to the third aspect of the present invention a single memristor is used, rather than the approximately 2 to 6 transistors that are used in conventional logic gates. In addition, a memristor is significantly smaller than a transistor, meaning that the total size reduction possible with the method of the second aspect of the present invention relative to a method that uses a conventional transistor-based logic device may be approximately 50 fold. A memristor is also more energy efficient than a transistor. Therefore, the method according to the third aspect of the present invention may be carried out with a smaller and more energy efficient device than the conventional method that uses a transistor-based logic device.

The method according to the third aspect of the present invention may have any one, or, to the extent that they are compatible, any combination of the following optional features.

The voltage states of the sequence of voltage states may be chosen so that they represent, or are associated with, input logical values to a logical operation. In other words, the method may comprise choosing an appropriate sequence of voltage states to be input into the memristor based on the input logical values of the logical operation whose output is to be determined.

The sequence of voltage states may comprise a sequence of voltage changes. In other words, each voltage state in the sequence of voltage states may comprise a change in voltage. Of course, in some cases the voltage “change” may be 0V, i.e. the voltages of two adjacent voltage states in the sequence of voltage states may be the same. Therefore, the sequence of voltage states may comprise a sequence of non-0V voltage changes and/or 0V voltage changes.

The method may comprise detecting a sign of the output current of the memristor; and determining an output of the logical operation based on the detected sign of the output current. The sign of the output current may change depending on the properties (i.e. magnitude and/or sign) of the voltage states and/or their order. Therefore, the sign of the output current may be indicative of the output of a logical operation performed on the sequence of voltage states and may be used to determine the output of a logical operation performed on the sequence of voltage states.

The method may comprise determining an output of: logical 1 if the sign of the output current is positive and logical 0 if the sign of the output current is negative; or logical 0 if the sign of the output current is positive and logical 1 if the sign of the output current is negative.

The method may comprise detecting a magnitude of the output current of the memristor; and determining an output of the logical operation based on the detected magnitude of the output current. The magnitude of the output current may change depending on the properties (i.e. magnitude and/or sign) of the voltage states and/or their order. Therefore, the magnitude of the output current may be indicative of the output of a logical operation performed on the sequence of voltage states and may be used to determine the output of a logical operation performed on the sequence of voltage states.

The method may comprise comparing the magnitude of the output current with a predetermined threshold value; and determining an output of: logical 1 if the magnitude is greater than the threshold value and logical 0 if the magnitude is less than the threshold value; or logical 0 if the magnitude is greater than the threshold value and logical 1 if the magnitude is less than the threshold value. The predetermined threshold value may be predetermined based on the type of logical operation that is to be performed.

The sequence of voltage states may comprise a first voltage state and a second voltage state; and the method may comprise detecting the property of the output current response of the memristor at, or after, the time of inputting the second voltage state. The property of the output current response of the memristor at, or after, the time of inputting the second voltage state may depend on both the first and second voltage states, i.e. on the characteristics (e.g. magnitude and/or sign) and/or order of the first and second voltage states. Therefore, the property of the output current response at, or after, the time of inputting the second voltage state may be used to determine the output of a logical operation performed on the first and second voltage states.

The second voltage state may be input into the memristor before the memristor has equilibrated to the first voltage state. Therefore the property of the output current response at, or after, the time of inputting the second voltage state will differ from the property that would be expected if the memristor were supplied with the second voltage state in isolation (i.e. when the memristor was in an equilibrium state). Therefore, the property of the output current response may depend on both the first and second voltage states, and/or on the order in which they are supplied to the memristor.

The method may comprise inputting a reading voltage into the memristor after inputting the sequence of voltage states; and detecting the property of the output current of the memristor at, or after, the time of inputting the reading voltage. For example, the reading voltage may be 0V. A voltage change from the second voltage state to the reading voltage, i.e. to 0V, will cause a current spike in the output current response of the memristor (which may be referred to as a response spike of the memristor). The property of the output current response at the time of the response spike may depend on the specific sequence of voltage states, and may therefore be used to determine an output of a logical operation performed on the sequence of voltage states. The reading voltage may be input into the memristor less than an equilibration time of the memristor after inputting the last voltage state in the sequence of voltage states.

The method may comprise representing different logical inputs to the logical operation with voltage states comprising different magnitude voltages. For example, the method may comprise representing a logical input of logical 0 with a first voltage state comprising a voltage (V_{A}) having a first magnitude and a logical input of logical 1 with a second voltage state comprising a voltage (V_{B}) having a second, larger, magnitude. An input sequence comprising a small voltage (e.g. V_{A}) followed by a large voltage (e.g. V_{B}) may lead to a large output current of the memristor, due to the large change in input voltage. Similarly, an input sequence comprising a large voltage (e.g. V_{B}) followed by another large voltage (e.g. the same voltage V_{B} or a different voltage) may also lead to a large output current of the memristor. In this case, there is no voltage change at the time of inputting the second large voltage if the first and second large voltages are the same, so there is no new current spike or change in the system. However, a large current is still measured at the time of inputting the second large voltage because a large current caused by the large change in voltage when the first large voltage was input has not yet decayed to zero (or significantly), due to the non-zero relaxation/equilibrium time of the memristor. In contrast, an input sequence comprising a small voltage (e.g. V_{A}) followed by another small voltage (e.g. the same voltage V_{A} or different) may lead to a small output current, because the small output current caused by the small change in input voltage when the first small voltage was input has not decayed to zero (or significantly) at the time of inputting the second small voltage. Therefore, by assigning a first logical value to a large output current and a second logical value to a small output current, the magnitude of the output current may be used to determine the output of a logical operation.

In addition, or alternatively, the method may comprise representing different logical inputs to the logical operation with voltage states comprising different sign voltages. For example, there may be two different voltage states that have voltages with the same magnitude but opposite signs (i.e. one is positive and the other is negative). A transition between a negative voltage and a positive voltage, or between a positive voltage and a negative voltage, may lead to a much larger voltage change, and therefore a much larger current spike, than a transition between voltages of the same sign. Therefore by assigning a first logical value to a larger output current and a second logical value to a smaller output current, the magnitude of the output current may be used to determine the output of a logical operation.

In some embodiments, both different magnitudes and different polarities may be used to represent different logical inputs. For example a large negative voltage −M may be used to represent logical 1 and a small positive voltage +m may be used to represent logical 0, or vice-versa (i.e. −m=logical 1 and +M=logical 0, or +M=logical 1 and −m=logical 0, or −M=logical 1 and +m=logical 0)). In this case, large/small may mean that M is at least ten times greater in magnitude than m, or at least 100 times, or at least 1000 times.

The method may comprise supplying a sequence of two voltage states to the memristor, wherein each of the voltage states comprises a voltage selected from the voltages V_{A} and V_{B}. In other words, the method may comprise supplying any one of four different sequential input combinations of the voltages V_{A} and V_{B} to the memristor, i.e. V_{A} then V_{A}, V_{A} then V_{B}, V_{B} then V_{A} or V_{B} then V_{B}. By assigning different logical values to the two voltages, e.g. V_{A} represents logical 0 and V_{B} represents logical 1, the four different sequential input combinations of voltages can be used to represent four different sequential input combinations of logical values, i.e. 0 then 0, 0 then 1, 1 then 0 or 1 then 1. As discussed above, the property of the output current response of the memristor may depend upon the characteristics (i.e. sign and/or magnitude) and/or order of the first and second voltage states, and therefore on whether the first and second voltage states comprise the voltages V_{A} or V_{B}. Therefore, the property of the output current response may depend on the particular sequence of V_{A} or V_{B} and therefore on the particular sequence of logical inputs to the logical operation (which are represented by V_{A} and V_{B}). As such, the property of the output current response may be used to determine an output of a logical operation, the inputs of which are the logical values represented by the voltage states.

The method may be a method of performing a Boolean logical operation.

The method may be a method of performing: an OR logical operation, an XOR logical operation, a NOR logical operation, a NOT logical operation, an AND logical operation, a NAND logical operation, an XNOR logical operation, or an addition logical operation.

The method may comprise using a property of the output current response to determine the sum of a sequence of logical inputs represented by the sequence of voltage stages.

The sequence of logical inputs may comprise a sequence of three, logical inputs.

The property of the output current response may be a magnitude of a maximum positive current of the current response.

The method may comprise using one or more properties (for example magnitude at one or more times) to determine a first logical output Cₒᵤₜ and a second logical output S, wherein the sum of a sequence of logical inputs represented by the sequence of voltage states is given by: sum=(2×Cₒᵤₜ)+S.

The method may comprise representing an input of logical 1 with a negative voltage −M and an input of logical 0 with a positive voltage +m, (or vice versa) wherein the magnitude of M is at least 10 times the magnitude of m, or at least 100 times the magnitude of m, or at least 1000 times the magnitude of m.

### BRIEF DESCRIPTION OF THE DRAWINGS

Embodiments of the present invention will now be discussed, by way of example only, with reference to the accompanying Figures, in which:

FIG. 1 is a graph showing a positive 1V square-wave voltage input supplied to a memristor;

FIG. 2 is a graph showing an output current of a memristor supplied with the voltage input of FIG. 1;

FIG. 3 is a schematic illustration of the short-term memory of a memristor;

FIG. 4 is a graph showing the effect of the order in which voltage changes are sent to a memristor, where S1=Δi_{0-A}(t), T1=Δi_{A-B}(t+1), T2=Δi_{0-B}(t), S2=Δi_{B-A}(t+1);

FIG. 5 is a graph showing the output current of a memristor for four different voltage inputs: (0.01V, 0.01V), (0.01V, 0.2V), (0.2V, 0.01V) and (0.2V, 0.2V);

FIG. 6 is a graph showing four different voltage input combinations for a memristor: (−0.1V, −0.1V), (−0.1V, +0.1V), (+0.1V, −0.1V) and (+0.1V, +0.1V);

FIG. 7 is a graph showing an output current for a memristor supplied with the voltage input of FIG. 6;

FIG. 8 is a graph showing the repeatability of the memristor doing XOR logic, where the XOR truth table is run 7 times. The threshold currents are shown as solid horizontal lines (one for +ve threshold and one for −ve threshold);

FIG. 9 is a graph showing an output current of a single memristor, wherein the positive currents perform an AND operation for a carry digit and the negative currents perform an OR operation for the summation digit;

FIG. 10 is a graph of the output current of a memristor acting as a full adder. For each operation, the first three input bits are the logical inputs and the system has one time-step to respond before a read spike is sent to it (as marked by a “*”).

### DETAILED DESCRIPTION OF THE PREFERRED EMBODIMENTS AND FURTHER OPTIONAL FEATURES OF THE INVENTION

### Experimental Configuration

The experimental data discussed in the following non-limiting examples were obtained using flexible TiO₂ sol-gel memristors comprising aluminium electrodes that were made using the method described in Gale 2011 (Gale et al, Aluminum Electrodes Effect the Operation of Titanium Dioxide Sol-Gel Memristors, arXiv:1106:6293v1 [cond-mat.mtrl-ci], http://arxiv.org/abs/1106.6293, 2011). The sol-gel was created as described in Gale 2013 (Gale et al, Drop-coated Titanium Dioxide Memristors, arXiv:1205:2885v2 [cond-mat.mtrl-ci], http://arxiv.org/abs/1205.2885) and the memristors were curved-type memristors (see Gale 2011). All tests on the memristors were performed with a Keithly 2400 Sourcemeter and data was recorded and analysed using MatLab. Each time-step was 0.02 s. The voltages used and voltage waveforms varied as discussed below. Gale 2013 and Gale 2011 are incorporated herein by reference.

### Physical Properties of Memristors

When there is a change in voltage, ΔV, across a memristor the device exhibits a current spike, the physical cause of which is discussed at length in Gale 2012. This current spike is highly reproducible and repeatable and is related to the size of the voltage change (ΔV) (See Gale 2012). The spike's size (as measured by the first measurement after the Keithley's changed voltage) is highly reproducible, the current then relaxes to a stable long-term value (this value is predictable and reproducible), and it takes approximately 2-3 seconds to get to this value.

This slow relaxation is thought to be the DC response of the memristor (see Gale 2012) and if a second voltage change happens within this time frame, its resulting current spike is different to that expected from the ΔV alone. The size and direction of this current spike depends on the direction of ΔV, the magnitude of ΔV and the short-term memory of the memristor. This leads to some interesting effects. For example, switching from a low to a high voltage or from a positive to a negative voltage, or visa-versa, may have a larger effect that the transitions from a low to a low voltage, or a high to a high voltage, or a negative to a negative voltage or a positive to a positive voltage. This larger effect can be thresholded to be a logical 1, allowing for the computation of basic logic.

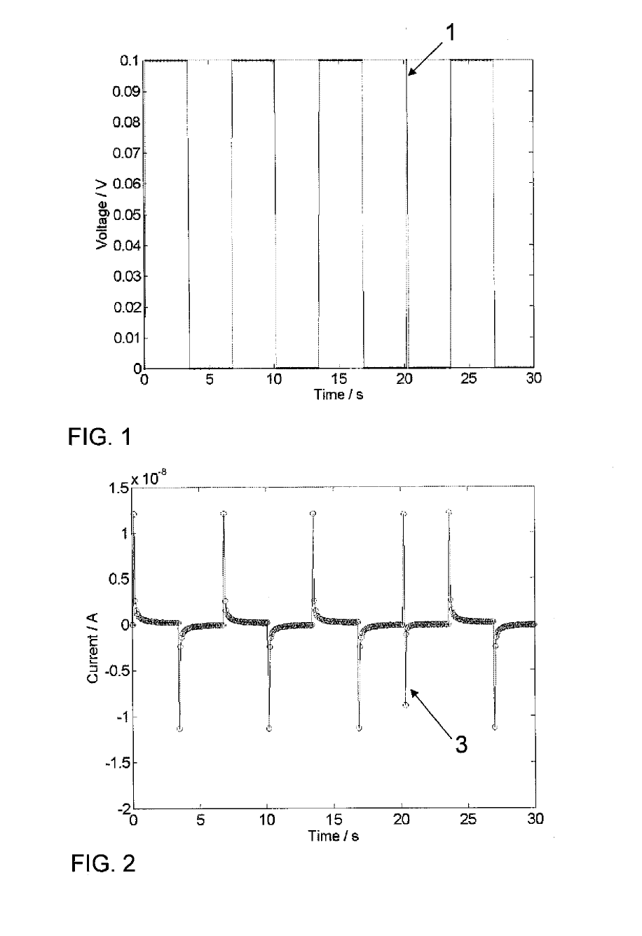

As an example, consider a memristor pulsed with a positive 1V voltage square wave as illustrated in FIG. 1 (where the pulses are repeated to demonstrate the repeatability) with a time-step of approximately 0.02 s. The current response of the memristor is shown in FIG. 2. Comparing FIGS. 1 and 2 shows that there is a positive current spike associated with the +ΔV transition from 0V to +1V and a negative current spike associated with the −ΔV transition from +1V to 0V. At approximately 20 s (reference numeral 1 in FIG. 1), the square wave was shortened to a single time-step of approximately 0.02 s. This time-step is significantly shorter than the equilibration time of the memristor, so that the memristor has not had sufficient time to equilibrate to the voltage of +1V before the voltage is reduced to 0V. As can be observed in FIG. 2, the memory of the system has caused the response spike (i.e. the negative current spike responding to the −ΔV from +1V to 0V, reference numeral 3 in FIG. 2) to be smaller than the previous response spikes (which occurred when the memristor was in an equilibrium state). The fact that this response spike is smaller than the previous response spikes suggests that there is some physical property of the device that has not adjusted to the +V value at the time of the −ΔV (this physical property may be the oxygen vacancies in the TiO₂). Thus, the response is subtractive in current and additive in resistance state.

Consider the following system: two voltages V_{A} and V_{B} are sent to the memristor separated by one time-step (i.e. before the memristor has equilibrated). V_{B} follows V_{A} and V_{B}>V_{A}. The voltage V_{A} can be associated with a logical value of logical 0 and the voltage V_{B} can be associated with a logical value of logical 1. Equivalently, we could say that the current of the memristor when V_{A} is input and the memristor is in an equilibrium state is our logical 0, and that the current of the memristor when V_{B} is input and the memristor is in an equilibrium state is our logical 1.

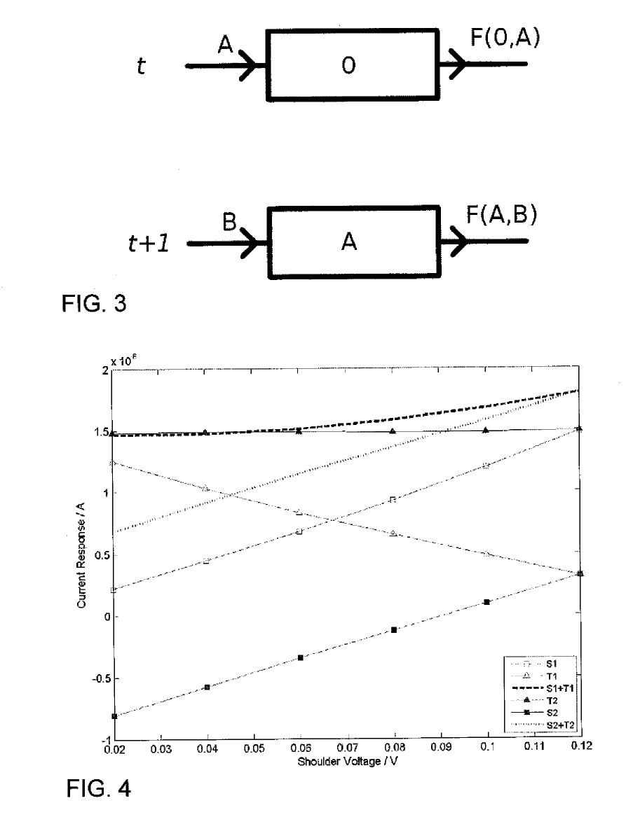

Supplying the voltage V_{A} at time t can be considered to be equivalent to inputting one bit of data, A, to the memristor at time t. This bit of data is stored for a short time as the state of the memristor (i.e. until the current has decayed back to the equilibrium current). Supplying the voltage V_{B} at a later time t+1 (before the memristor has equilibrated to the voltage V_{A}) can be considered to be equivalent to inputting a second bit of information to the memristor at time t+1, which interacts with the stored bit A to give an output of F(A,B), where F is some function of A and B (note that at the time t the output is F(0,A), as this is the response of the memristor to V_{A} after zeroing of the memristor). This arrangement is illustrated schematically in FIG. 3. Depending on how A and B are implemented (e.g. the magnitudes and/or signs of the voltages V_{A} and V_{B} and/or their order) and how we assign the output values, F can be a function that does Boolean logic or Imp logic or another type of logical operation.

The type of operation illustrated in FIG. 3 may be termed memristor sequential logic, because it allows the result of the logical operation to be computed over time by storing a state and allowing it to interact with the subsequent input. Therefore, a one terminal device can do two-input (or higher) logical operations.

To try to understand some further subtleties of this apparent “addition”, consider the following system: two voltages are sent to the memristor, one after the other separated by one time-step (i.e. before the memristor has equilibrated), where V_{B}>V_{A} and V_{B}=0.12V. FIG. 4 illustrates the sizes of the two resulting current spikes as a function of increasing V_{A}. FIG. 4 relates to two different situations: 0→V_{A}(t)→V_{B}(t+1) (S1, T1 and S1+T1 in FIG. 4) and 0→V_{B}(t)→V_{A}(t+1) (T2, S2 and S2+T2 in FIG. 4). These two situations are drastically different if we look at the transitions, ΔV, as the second situation has a negative ΔV_{B-A}, whereas all the other transitions are positive. The first situation shows that if the smaller voltage is sent first (i.e. the V_{A}→V_{B} operation), the current of the first transition, Δi_{0-A} (S1 in FIG. 4), increases with the size of V_{A}, and the current of the second transition, Δi_{A-B} (T1 in FIG. 4) decreases with the size of V_{A}, due to the decrease in the effective ΔV_{A-B}. However, the sum of these two effects is non-linear, so that the total current transferred (approximated as the sum of the spikes here, but actually the area under the two current transients) is not the same as that shown for the second situation (until V_{B}=V_{A}). This shows that more current is being transferred in the first situation and demonstrates that the spikes are dependent on ΔV. Furthermore, it makes it clear that Δi_{0-A}+Δi_{A-b}≠Δi_{0-B}+Δi_{B-A} (except in the trivial case where V_{B}=V_{A}) and that spike based ‘addition’ is non-commutative and therefore the order in which the spikes are sent is relevant.

The operation V_{A}→V_{B} actually consists of three transitions, i.e. V₀→V_{A}→V_{B}→V₀, where V₀ is V=0V, i.e. the starting and reading position.
The first transition V₀→V_{A} is a positive ΔV and so gives a positive current spike, +I(A) at t;
The second transition V_{A}→V_{B} is a positive ΔV and also gives a positive current spike, +I(B) at t+1;
The third transition V_{B}→V₀ is a negative transition and so gives a negative current spike, −I at t+2;
Further current readings at V₀ will have non-zero current until the memristor's short-term memory is lost (i.e. after the equilibration time, τ)

If the order is switched so that V_{B}, is input at time t and V_{A} at time t+1, then there will be a negative current at time t+1 (−I(A)) as V_{B}>V_{A} so going from V_{B}→V_{A} is a negative transition. As discussed above, the operation V_{A}→V_{B}≠the operation V_{B}→V_{A}, i.e. it is non-commutative. This directionality allows the memristor to perform Implication or other order based logic, i.e. the order that the bits are input matters. Another important concept is the concept of “bounce-back”, which is the current response that happens when the voltage is switched off, i.e. the V_{B}→V₀ transition. This current can be large enough to take a logical value (dependent on the system), allowing for logical computation. An important point is that the response from a change in direction of the voltage (i.e. +V→−V) is bigger in magnitude that the response from two spikes of the same voltage or the same direction (i.e. +V→+V).

### Logic Using Current Spikes in Memristors

We can do logic, such as Boolean logic, with the current spike interactions by sending the second bit of information (i.e. the second voltage or voltage change) one time-step (e.g. 0.02 s) after the first bit of information. We take the input as the current spikes from the voltage level. The output is the response current as measured after the 2^{nd} bit of information. After a logic operation the device is zeroed by being taken to 0V for approximately 4 s, which removes the memristor's memory. We have some freedom in how we assign the ‘1’ and ‘0’ logical states to device properties and different types of logic can be achieved by assigning the logical states in different ways.

As discussed above, there are at least two variables that we can utilise when assigning logical values: the magnitude, e.g. as represented by M for a high magnitude and m for a low magnitude, and the sign, e.g. as represented by + for a positive sign and − for a negative sign. To implement logical operations, voltage states can be applied for one time-step and the response can be recorded at the same frequency. In between logical operations the devices can be left for longer than the equilibration time of the device to zero the memristor by removing its short term memory.

The following physical rules may be applicable or important in some embodiments of the present invention.

A. Directionality

The memristor naturally implements Implication. The memristor is directional: e.g. the response at t+1 for A→B does not equal the response at t+1 for B→A. The reason for this is that the memristor responds to the difference in input voltage. This naturally allows memristor-based sequential logic to compute implication logic, because Implication, IMP or ‘→’ requires that 0→1≠1→0, and therefore that the order in which the two values are input has meaning. Naturally sequential logic, as it separates the values in time, implements this ordering. Note that sequential logic is a scheme for how the memristor can enact logical operations. Implication is an example of a logical operation, and implication logic is the name for the logical set of [IMP,FALSE] required for functionally-complete computation.

B. ‘Summation’

If the logical ‘1’ is taken as being a high voltage, i.e. M instead of m, then more energy is imparted to the system from logical combinations like [1,1] that by logical combinations such as [0,0]. This approach can allow for the creation of memristor-based time-limited summators of use in leaky integrate and fire neurons.

C. ‘Bounceback’

The application of a voltage change produces a resultant current spike in the direction of the difference between the starting voltage and the ending voltage, e.g. the first voltage change V₀→V_{A} causes a positive current response +i_{A} if V_{A} is positive and a negative current response −i_{A} if V_{A} is negative. If the system is then returned to zero, there is a smaller current spike of the opposite polarity, i.e. −i₀ and +i₀ respectively for the two examples mentioned above. If several spikes are input before returning to zero, i.e. a sequence of [V₀, V_{A}, V_{A}, V₀] the current spike is larger than would be the case for [V₀, V_{A}, V₀], although not twice as large due to losses in the system.

D. ‘Diminishing Returns’

The effect of additional spikes of the same size and polarity, occurring within the window of the memristor's short term memory decreases. A similar effect is seen with changing polarity, in that changing polarity can cause a larger response (than not) but this response is smaller with successive voltages. For example, the response spike to [V₀, +V_{A}, −V_{A}, +V_{A}, −V_{A}] is smaller than the response spike to [V₀, +V_{A}, −V_{A}].

Knowledge of these rules and effects allows for the design of logical computation systems that perform a surprising amount of computation with only a single memristor. From experiments, it appears that that the summation effect may be more important in magnitude logic, whereas the ‘bounceback’ effect may be more relevant in polarity logic (although both may affect the outcome in both cases). As these effects can be balanced and set in opposition to each other, the richest effects may come from using mixed logics.

The following non-limiting examples demonstrate some approaches for doing logic operations with a memristor.

Magnitude Logic

Consider an arrangement where the memristor is sequentially supplied with a first voltage of either V_{A} or V_{B} and then a second voltage of either V_{A} or V_{A} one time-step after the first voltage, where V_{B}>V_{A}. In this specific example, V_{A}=0.01V and V_{B}=0.2V (in an alternative case, V_{A} could instead be 0V, which has an advantage of being a lower power arrangement). In this case:
The operation V_{A}(t)→V_{A}(t+1) gives a small, positive I(t+1) and a small, negative I(t+2). Although ΔV=0 at time t+1, so there is no new current spike or change in the system at time t+1, the small, positive current in response to the ΔV=V_{A} at time t has not yet decayed completely at time t+1 (due to the non-zero equilibration time of the memristor), so there is still a small, positive current at time t+1 (smaller than the current at time t because this current has decayed between times t and t+1);
The operation V_{A}(t)→V_{B}(t+1) gives a large, positive I(t+1) and a large negative I(t+2);
The operation V_{B}(t)→V_{A}(t+1) gives a large, negative I(t+1) and a small, negative I(t+2);
The operation V_{B}(t)→V_{B}(t+1) gives a large, positive I(t+1) and a large negative I(t+2). Again, the large, positive current at time t+1 is due to the large, positive current generated at time t in response to the ΔV=VB, which has only partly decayed by the time t+1.

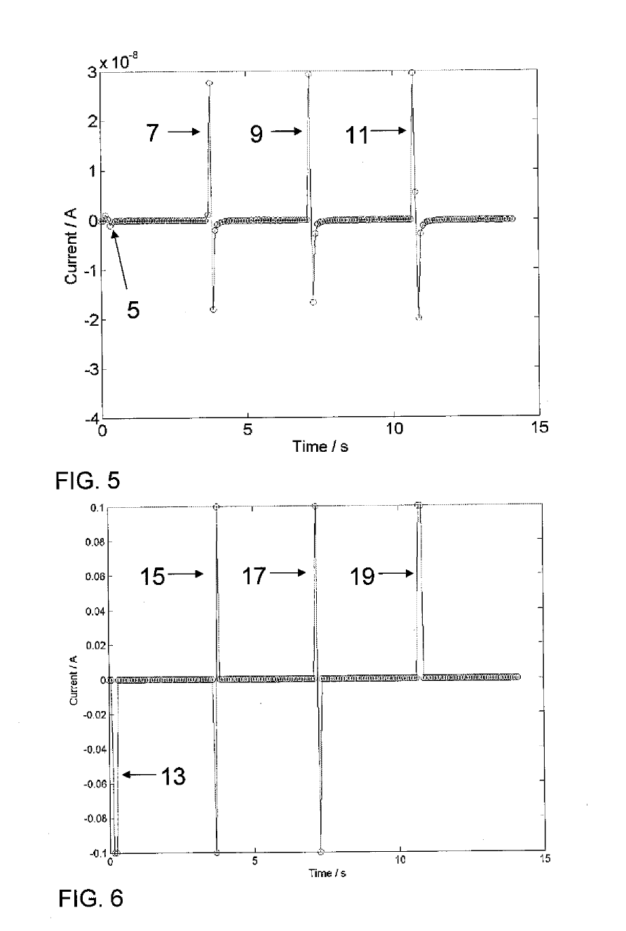

The current data from these voltage inputs are shown in FIG. 5. In more detail, reference numeral 5 is the current response for the operation V_{A}→V_{A}, reference numeral 7 is the current response for the operation V_{A}→V_{B}, reference numeral 9 is the current response for the operation V_{B}→V_{A} and reference numeral 11 is the current response for the operation V_{B}(t)→V_{B}(t+1). The slightly larger negative current at time t+2 for the operation V_{B}(t)→V_{B}(t+1) (relative to the other operations) visible in FIG. 5 is due to the effects of the operation V_{B}(t)→V_{B}(t+1) putting more energy into the system (see the B. Summation section above) than the other operations.

If we take V_{B} (i.e. 0.2V in this example) to be an input of logical 1 to a logic operation and V_{A} (i.e. 0.01V in this example) to be an input of logical 0 to a logic operation, we can assign a few different logic systems to the output current of the memristor.

If we consider the current output at time t+1 and we take a large current (i.e. a current magnitude above a predetermined threshold value, >18 nA in this example) as logical 1 and a small current (i.e. a current magnitude below the predetermined threshold value) as logical 0, we get the results shown in Table I, which corresponds to the truth table for the OR logic operation (it can be seen from FIG. 5 that when a “1” is input, there is a large current spike output). Therefore, in this configuration the memristor can be used as an OR logic gate, by considering the magnitude of the current at time t+1.

TABLE I
Logical output determined for different logical inputs when
considering the magnitude of the current at time t + 1.

| First input | | Second input | | Output | |
|---|---|---|---|---|---|
| | Logical | | Logical | | Logical |
| Voltage/V | value | Voltage/V | value | Current | value |
| 0.01 | 0 | 0.01 | 0 | Small | 0 |
| 0.01 | 0 | 0.2 | 1 | Large | 1 |
| 0.2 | 1 | 0.01 | 0 | Large | 1 |
| 0.2 | 1 | 0.2 | 1 | Large | 1 |

If instead we consider the sign of the output current at the time t+1 and we take a positive current as logical 1 and a negative current as logical 0, we get the results shown in Table II, which corresponds to the truth table for implication logic (IMP), which arises as the transition from V_{B}(t)→V_{A}(t+1) is negative. Thus, the memristor can be thought of as doing OR logic with the magnitude of the output current at t+1 and IMP logic with the sign of the output current at t+1, i.e. at the same time. Therefore it is possible to get two bits of output data for two bits of input data.

TABLE II
Logical output determined for different logical inputs
when considering the sign of the current at time t + 1.

| First input | | Second input | | Output | |
|---|---|---|---|---|---|
| | Logical | | Logical | | Logical |
| Voltage/V | value | Voltage/V | value | Current | value |
| 0.01 | 0 | 0.01 | 0 | Positive | 1 |
| 0.01 | 0 | 0.2 | 1 | Positive | 1 |
| 0.2 | 1 | 0.01 | 0 | Negative | 0 |
| 0.2 | 1 | 0.2 | 1 | Positive | 1 |

Similarly, if we consider the current output at the time t+2 and we take a large current (i.e. a current magnitude above a predetermined threshold) as logical 1 and a small current (i.e. a current magnitude below a predetermined threshold) as logical 0, we get the results shown in Table III.

TABLE III
Logical output determined for different logical inputs when
considering the magnitude of the current at time t + 2.

| First input | | Second input | | Output | |
|---|---|---|---|---|---|
| | Logical | | Logical | | Logical |
| Voltage/V | value | Voltage/V | value | Current | value |
| 0.01 | 0 | 0.01 | 0 | Small | 0 |
| 0.01 | 0 | 0.2 | 1 | Large | 1 |
| 0.2 | 1 | 0.01 | 0 | Small | 0 |
| 0.2 | 1 | 0.2 | 1 | Large | 1 |

It can be seen from these examples that by associating appropriate logical values to appropriate input voltages V_{A} and V_{B} and by assigning an appropriate output logical value based on one or more properties of the output current of the memristor (e.g. the magnitude or the sign of the output current) detected at or after the time of sending the second voltage (e.g. the time t+1 or the time t+2) the memristor can be used to determine the output of a logic operation.

As discussed in the following examples, we can also allow the use of negative input voltages to achieve equivalent or different logic operations based on the signs of the input voltages. Of course, it is also possible to carry out logic operations by considering both the sign and the magnitude of the input voltages (e.g. see the mixed logical rules section below).

As illustrated by these (non-exhaustive and non-limiting) examples, a large number of different logic operations may be implemented using a (single) memristor by choosing appropriate values for the following parameters:
the values of the input voltages;
how input logical values are assigned to the input voltages (e.g. based on the sign and/or magnitude of the input voltages);
the value of the predetermined threshold when considering the magnitude of the output current;
how an output logical value is assigned based on the output current (e.g. what property of the output current is used, i.e. sign and/or magnitude, and what time the output current is considered)

Positive/Negative Logic

We can use the sign of the input voltage to associate a logical value with the input voltage. For example, we can designate a positive (+V) as being a logical value of logical 1 and a negative voltage (−V) as being a logical value of logical 0. To simplify matters we can also make the magnitudes of the positive and negative voltages the same, i.e. V_{A}→V_{B}, although this is not essential.

A transition from +V→V gives rise to a small, positive current. At the time of the transition (i.e. the time t+1), ΔV=0, so there is no new response spike or change in the state of the system. However, a small positive current is still observed at the time t+1 because the current spike caused by the first transition from V(0) to +V at the earlier time t has not yet decayed to zero. Similarly, −V→V has a small, negative output current for similar reasons. The transitions +V→V and −V→+V have a large ΔV (a maximum of 2V, but the effective value of the first input V is decaying with time as the state decays) and these both have a large current: +V→−V has a large negative current at t+1 and a medium positive current at t+2, −V→+V has a large positive current at t+1 and a medium negative current at t+2.

If we consider the magnitude of the output current at time t+1 and we take the output at being logical 1 for a high magnitude output current (i.e. a current magnitude greater than a predetermined threshold—1.25×10⁻⁸ A in this example)) and logical 0 for a low magnitude current (i.e. a current magnitude less than a predetermined threshold) then we get the results shown in Table V, which corresponds to the XOR logic operation (exclusive OR). A similar system could be designed in which the magnitude of the current is considered after t+1, but this alternative arrangement may be slower than the arrangement described in this example.

TABLE V
Logical output determined for different logical inputs when
considering the magnitude of the current at time t + 1

| First input | | Second input | | Output | |
|---|---|---|---|---|---|
| | Logical | | Logical | | Logical |
| Voltage/V | value | Voltage/V | value | Current | value |
| −V | 0 | −V | 0 | Small | 0 |
| −V | 0 | +V | 1 | Large | 1 |
| +V | 1 | −V | 0 | Large | 1 |
| +V | 1 | +V | 1 | Small | 0 |

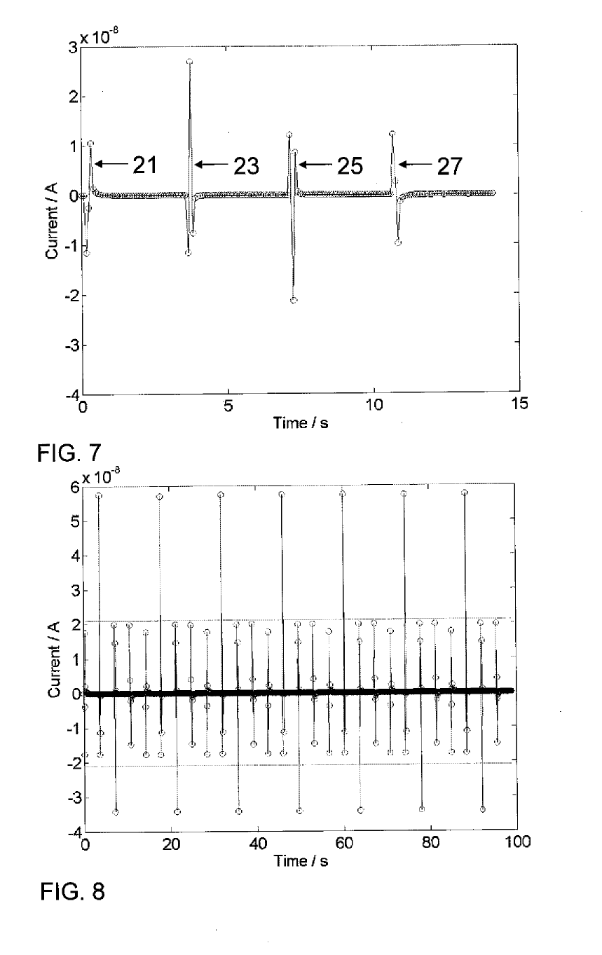

A graph of the different combinations of sequential voltage inputs of Table V is shown in FIG. 6, where 13 is −V,−V (0,0), 15 is −V,+V (0,1), 17 is +V,−V (1,0) and 19 is +V,+V (1,1). The corresponding current outputs are shown in the graph of FIG. 7, where 21 is the current response to the −V,−V input, 23 is the current response to the −V,+V input, 25 is the current response to the +V,−V input and 27 is the current response to the +V,+V input.

It can be seen from FIG. 7 that we get a high magnitude of current if (and only if) the two input voltages are of different signs, i.e. we have 0,1 or 1,0, which corresponds to the XOR (exclusive OR) logic operation.

With a pause between operations to allow the memristor to lose its memory (i.e. to return to an equilibrium state) the XOR operation is reproducible, as shown in FIG. 8. In particular, FIG. 8 shows that the XOR operation is very reproducible when it is run seven times in succession. The current thresholds (i.e. positive and negative) used to distinguish between an output of logical 0 and logical 1 are shown as horizontal lines in FIG. 8.

With this logic system we have used the same magnitude of input voltages and have used the sign of the input voltage to associate a logical value with the input voltage.

In some systems a high enough magnitude current may cause an applied voltage to switch from a negative sign to a positive sign, allowing the onward transmission of logical values. In particular, it may be possible to connect memristors together so that a high magnitude current pulse from one memristor can affect the value of the voltage applied to the other memristor. For example, if a voltage was applied across a second memristor connected in series with a first memristor being operated in a way as described above, then the resulting current pulse when it goes through the second memristor may change the effective applied voltage for the second memristor. As changing the effective applied voltage for the second memristor will cause a current response on the second memristor, this technique may allow the movement/transfer of logical values from one memristor to another, allowing the memristor logic gates to be wired together to make computer components.

In the examples discussed above the memristor is used in a serial logic gate arrangement where the bits are separated in time. This allows us to do logic operations with one memristor at the speed of the spikes (fast) rather than at the speed of equilibration (slow). This approach also allows us to do logic with two-terminal (one port) devices, because the extra ‘complexity’ of the operation is contained within the time domain. Essentially, we use the memristor's short term memory to hold the first bit and do the calculation. This demonstrates that memristors can act as the processor and memory store in one.

The memristor is acting similarly to a sequential logic circuit, where the combinatorial logic is combined with the memory store. Furthermore, the memristor logic gate is asynchronous because there is no need for a clock pulse, but there are fewer issues of race hazard because the second bit must arrive within the time window of the memristor's memory.

The memristor is very low power, especially if operated at the example voltages and currents discussed above (of course, it is possible to operate at high voltages and/or currents if desired).

### Mixed Logical Rules and Arithmetic Circuits

By using mixed logic, i.e. a combination of magnitude and positive/negative (polarity) logic, it is possible to form other types of logic devices. For example, it is possible to form an AND gate using mixed logic.

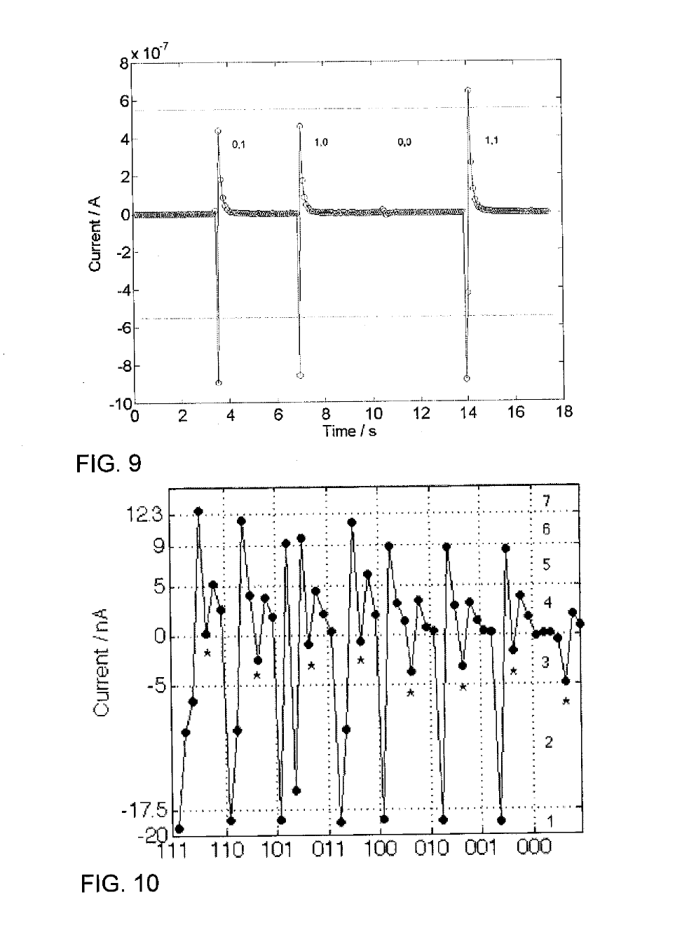

An AND gate can be produced by using an input voltage of −M (‘M’ meaning a large magnitude voltage), e.g. −0.5V, to represent logical 1 and an input of +m (‘m’ meaning a small magnitude voltage), e.g. +0.001V, to represent logical 0. FIG. 9 shows the current output of the memristor for the logical inputs [01], [10], [00] and [11]. If we take the response output as logical 1 if the positive current is over a suitable chosen predetermined threshold (in this case 0.55 μA—shown as a positive horizontal line in FIG. 9), and logical 0 if not, then we get the results shown in Table VI.

TABLE VI
Logical output determined for different logical inputs
when considering the magnitude of the positive current,
where ‘small’ means below a predetermined threshold -
shown with a horizontal line in FIG. 9

| First input | | Second input | | Output | |
|---|---|---|---|---|---|
| | Logical | | Logical | | Logical |
| Voltage/V | value | Voltage/V | value | Current | value |
| +m | 0 | +m | 0 | Small | 0 |
| +m | 0 | −M | 1 | Small | 0 |
| −M | 1 | +m | 0 | Small | 0 |
| −M | 1 | −M | 1 | Large | 1 |

Due to the summation effect discussed above, the amount of energy in the [11] system is larger than the amount of energy in the [01], [10] and [00] systems, and this causes a larger ‘bounceback’ response at the time t+2 for the [11] system which can be measured in the positive current response and used to distinguish the [11] system from the other systems (by setting an appropriate threshold for the positive current at the time t+2—as shown in FIG. 9).

Where we instead limit ourselves to the negative current part of the device response shown in FIG. 9, the magnitude of the output picks out an inclusive OR operation, in that only parts of the truth table that have a response over the negative current threshold shown in FIG. 9 are those that contain a logical 1 input (because the presence of a large negative current spike in the response requires a logical 1 input).

TABLE VII
Logical output determined for different logical inputs
when considering the magnitude of the negative current,
where ‘small’ means below a predetermined threshold -
shown with a horizontal line in FIG. 9

| First input | | Second input | | Output | |
|---|---|---|---|---|---|
| | Logical | | Logical | | Logical |
| Voltage/V | value | Voltage/V | value | Current | value |
| +m | 0 | +m | 0 | Small | 0 |
| +m | 0 | −M | 1 | Large | 1 |
| −M | 1 | +m | 0 | Large | 1 |
| −M | 1 | −M | 1 | Large | 1 |

The next level of complexity up from individual logic gates is arithmetic circuits, such as half-adders, full adders, multipliers and so on. To build a computer you first build logic gates and then arithmetic circuits including the logic gates.

As discussed above, If we decide that logical 1 is equal to a negative and large voltage, −V_{B} and that logical zero is equal to a positive and smaller voltage +V_{A} and we only use the magnitude of the current for the output and we chose our threshold correctly we can get a system where at t+2 it outputs AND(A,B).

By adding in a fixed logical 1, that is a negative pulse to set the memristor up before sending the logic to it, we can get a device that performs XOR(A,B) at time t. Note that the starting pulse is the same regardless of the logic input afterwards, so it is like a clocking pulse or switch and not part of the logic. In other words, a clocking pulse is sent to the memristor to put the memristor into a known state before the logic is sent to the memristor.

The XOR and AND operations are interesting because their combined outputs correspond to the truth table for a 2-bit half-adder, which is shown in Table VIII (Σ is the summation digit indicating numerical 1 when it is equal to logical 1 and C is the carry digit indicating numerical 2 when it is equal to logical 1 (it is the carry digit that would be fed into another half-adder to count up to numbers greater than 2)). A half-adder is equivalent to two logic gates and with current technology requires 5 to 6 transitors.

TABLE VIII
Truth table for a 2-bit half-adder

| A | B | Σ | C |
|---|---|---|---|
| 0 | 0 | 0 | 0 |
| 0 | 1 | 1 | 0 |
| 1 | 0 | 1 | 0 |
| 1 | 1 | 0 | 1 |

With the logic devices of the present invention such a two-bit half-adder can be implemented using two memristors connected in series with an information line going through both. The second memristor can also have a pulse line where the ‘1’ signal is input before the logic data is sent, making it act as the XOR (Σ bit out). The first memristor has no pulse to set it up so it acts like an AND gate (the C carry bit). Diodes can be used to prevent the clocking signal from flowing into the first memristor. This allows us to build a half-adder with two memristors. The output from the second memristor at time t is the summation and the output from the first memristor at time t1+1 is the carry.

With the addition of an OR gate to combine their carry outputs (C), two half-adders can be combined to make a full adder.

By making other appropriate combinations of logic gates it is possible to build other types of arithmetic circuit.

By including inductors either within the circuit or in a separate circuit next to the memristor it may be possible to convert the current spike of the memristor into a voltage change to be applied to another memristor downstream of the first memristor. This voltage change will cause a current spike in the output current of the second memristor, and thus multiple memristors may be able to communicate in a logical cascade by connecting such circuits in series.

### Full Adder

It is possible to produce a full-adder using a single memristor. A truth table for a full adder is shown in Table IX below.

TABLE IX
Truth table for a one-bit full adder

| | |
|---|---|
| Inputs | Outputs |

| A | B | Cᵢₙ | Cₒᵤₜ | S |
|---|---|---|---|---|
| 0 | 0 | 0 | 0 | 0 |
| 1 | 0 | 0 | 0 | 1 |
| 0 | 1 | 0 | 0 | 1 |
| 1 | 1 | 0 | 1 | 0 |
| 0 | 0 | 1 | 0 | 1 |
| 1 | 0 | 1 | 1 | 0 |
| 0 | 1 | 1 | 1 | 0 |
| 1 | 1 | 1 | 1 | 1 |

The current response of a memristor operated as a full-adder is illustrated in FIG. 10. The three input bits (corresponding to two input bits and one carry bit) are input as a series of spikes using mixed logic with logical input ‘1’ represented by −M (−0.5V) and logical input ‘0’ represented by +m (+0.001V). The input sequence is [A, B, C, 1, 2, 3, 4], with the logic input at times t_{A} to t_{C}, the response spike recorded at time t₁ and an extra read voltage of −0.15V input at time t₂. This gate may require a clock to operate. The input voltage from time t₃ onwards is V=0 (or put another way there is no input voltage from time t₃ onwards).

FIG. 10 shows the response of the memristor to this scheme, for the three inputs of a full adder, the read spike at time t₂ is marked with an * to make it easier to understand, and the data of the memristor losing its short-term memory is not shown. The system has one time-step to respond after the three logical inputs before the read spike is sent in.

From this set-up the following things can be deduced from knowing the maximum positive and negative current spikes within 4 time-steps of an input (although this requirement can be relaxed if the maximum current is instead recorded within the ranges in between zeroing the system, which can be done with knowledge of the read pulse clock), i.e. within time t₁ to t₄ following the end of the inputs at times t_{A} to t_{C}. In some embodiments, it may be possible to deduce these things within 3 time-steps of the end of the inputs at times t_{A} to t_{C}, by omitting the extra read voltage input at time t₂.

The resulting information from the current is thus:

1) if a negative current is recorded in the range −17.5 to −20 nA: we have had a ‘1’ input into the system

2) if a negative current is recorded in the range −5 to −17.5 nA: we have a carry bit from the operation

3) if a negative current is recorded in the range 0 to −5 nA: we have had a zero in the system (this is redundant information)

4) if the maximum positive current is recorded in the range 0 to +5 nA: the result of the calculation is ‘0’

5) if the maximum positive current is recorded in the range +5 to +9 nA: the result of the calculation is ‘1’

6) if the maximum positive current is recorded in the range +9 to +12.3: the result is ‘2’ (or ‘1’ for the carry bit, ‘0’ for the summation bit)

7) if the maximum positive current is recorded over 12.5 nA: the result is ‘3’ (or ‘1’ for both the carry and summation bit in binary logic).

The output in the negative is purely a result of the input voltages to the system. The positive system includes the ‘bounceback’, and the summation effect as probed by the read voltage which gives thresholded values of the memristor's state.

With switches, it would be possible to send on the logical result as binary. Region two of the plot in FIG. 10 encodes the carry bit for the operation, because only if there are two −M spikes (which encode ‘1’) within 3 time-steps of each other we will see a current response in that range. The summation bit is not encoded in as direct a manner, the maximum of the positive currents encodes the numerical sum, and so the summation bit for the value 3 is in a different place to that for the value 1. If we only require knowledge of the carry and summation bit, we can do without the read voltage and corresponding spikes. Changing the values of M and m can tune the effect and might allow us to change the relative values of the output spikes.

The example shown here takes in 3 bits of information and the output includes: the sum, the value of the carry bit, whether the input includes a 1, whether the input includes a 0 and, from the precise value of the spikes at t₂ and from a more precise thresholding over the outputs, we can learn where the zero is in the input sequences ([011,101,110]) and where the ‘1’ is in the input sequences ([001,010,100]). These last two points are interesting as it suggests that the memristor Full Adder shown here does not destroy information by the operation, however the gate is not-reversible (as this would require the ability to run time backwards to reverse the physics). Therefore, with appropriate design, the memristor can be made to compute more information. As the memristor has to be zeroed, and this takes time, it is advantageous for the memristor to do the maximum amount of processing, which suggests that a processor built out of memristors would have a lower clock speed but may compute more bits of information each cycle.

The use of memristor summation approaches in the full adder scheme is similar to how neurons work. For example three ‘1’ inputs received one after the other causes the largest response spike and the only positive t₂ spike. Either of these outputs could be linked to a thresholded switch which could release a current or voltage spike and thus act like a leaky integrate and fire neuron. The diminishing returns effect could enforce a refractory period. As neurons work by converting a rate-coded spiking voltage to a current spike at the synapse and then to a voltage spike, all of which can be considered transmission of a logical ‘1’, the memristor with its action whereby input and output are current and voltage, could be ideally suited to neuromorphic computing.

1. A logic device comprising:
a memristor having:
an input for receiving a sequence of voltage states which represent a sequence of logical inputs for a logical operation; and
an output for an output current response triggered by the sequence of voltage states; and
a determining unit arranged to determine an output of the logical operation from the output current response.

2. The logic device according to claim 1, including a current detector configured to detect a sign of an output current of the memristor, wherein the determining unit is configured to determine the output of the logical operation based on the detected sign of the output current.

3. The logic device according to claim 1, including a current detector configured to detect a magnitude of an output current of the memristor, wherein the determining unit is configured to determine the output of the logical operation based on the detected magnitude of the output current.

4. The logic device according to claim 1 wherein the logic device comprises a Boolean logic gate.

5. The logic device according to claim 1, wherein the logic device comprises one or more of: an OR logic gate, an XOR logic gate, a NOR logic gate, a NOT logic gate, an AND logic gate, a NAND logic gate, an XNOR logic gate, an adder or a half-adder.

6. The logic device according to claim 1, wherein the determining unit is arranged to determine the sum of the sequence of logical inputs from the output current response.

7. The logic device according to claim 6, wherein the determining unit is arranged to determine the sum of the sequence of logical inputs based on a magnitude of a maximum positive current of the current response.

8. The logic device according to claim 1, wherein the determining unit is arranged to determine a first logical output Cₒᵤₜ and a second logical output S from the current response, wherein the sum of the sequence of logical inputs is given by sum=(2×Cₒᵤₜ)+S

9. A logic device comprising:
a memristor having an input and an output;
a current detector arranged to detect a property of an output current spike from the memristor; and
a logical operation determining unit arranged to determine an output of a logical operation based on the detected property of the output current spike that is output in response to a sequence of voltage changes applied at the input of the memristor;
wherein the sequence of voltage changes represent a sequence of logical inputs for the logical operation.

10. A method of performing a logical operation, comprising:
inputting a sequence of voltage states into a memristor to trigger an output current response; and
using a property of the output current response of the memristor to determine an output of a logical operation performed on the sequence of voltage states.

11. The method according to claim 10, wherein the sequence of voltage states comprises a sequence of voltage changes.

12. The method according to claim 10, wherein the method comprises:
detecting a sign or magnitude of the output current of the memristor; and
determining an output of the logical operation based on the detected sign or magnitude of the output current.

13. The method according to claim 12, wherein the method comprises determining an output of:
logical 1 if the sign of the output current is positive and logical 0 if the sign of the output current is negative; or
logical 0 if the sign of the output current is positive and logical 1 if the sign of the output current is negative.

14. The method according to claim 12, wherein the method comprises:
comparing the magnitude of the output current with a predetermined threshold value; and
determining an output of:
logical 1 if the magnitude is greater than the threshold value and logical 0 if the magnitude is less than the threshold value; or
logical 0 if the magnitude is greater than the threshold value and logical 1 if the magnitude is less than the threshold value.

15. The method according to claim 10, wherein:
the sequence of voltage states comprises a first voltage state and a second voltage state; and
the method comprises detecting the property of the output current response of the memristor at, or after, the time of inputting the second voltage state,
wherein the second voltage state is input into the memristor before the memristor has equilibrated to the first voltage state.

16. The method according to claim 10, wherein the method comprises:
inputting a reading voltage into the memristor after inputting the sequence of voltage states; and
detecting the property of the output current of the memristor at, or after, the time of inputting the reading voltage.

17. The method according to claim 10, wherein the method comprises representing different logical inputs to the logical operation with voltage states comprising different magnitude voltages or different sign voltages.

18. The method according to claim 10, wherein the method comprises using a property of the output current response to determine the sum of a sequence of logical inputs represented by the sequence of voltage states.

19. The method according to claim 18, wherein the property of the output current response is a magnitude of a maximum positive current of the current response.

20. The method according to claim 10, wherein the method comprises using one or more properties of the output current response to determine a first logical output Cₒᵤₜ and a second logical output S, wherein the sum of a sequence of logical inputs represented by the sequence of voltage states is given by sum=(2×Cₒᵤₜ)+S.
